(19) United States
(12) Patent Application Publication
(10) Pub. No.: US 2007/0194470 A1
(43) Pub. Date: Aug. 23, 2007

(54) DIRECT LIQUID INJECTOR DEVICE

(75) Inventor: Jay Brian Dedontney, Prunedale, CA (US)

Correspondence Address: GIFFORD, KRASS, SPRINKLE,ANDERSON & CITKOWSKI, P.C, PO BOX 7021, TROY, MI, 48007-7021, US

(73) Assignee: Aviza Technology, Inc., Scotts Valley, CA (US)

(21) Appl. No.: 11/676,346

(22) Filed: Feb. 19, 2007

Related U.S. Application Data
(60) Provisional application No. 60/774,318, filed on Feb. 17, 2006.

(51) Int. Cl. B01F 5/04; C23C 16/00

(52) U.S. Cl. 261/76; 261/DIG. 25; 118/715

(57) ABSTRACT

A device for mixing, vaporizing and communicating a precursor element in a highly conductive fashion to a remote processing environment. A supply meter admits a precursor liquid according to a piezo controlled valve, which communicates therewith for controlling flow into a mixing manifold. A vaporizer manifold in cooperation with a carrier gas supply provides a carrier gas for contemporaneous delivery into the mixing manifold. A vaporizing component having at least a heating element in communication with the mixing manifold, in cooperation with a mixing (frit) material provided in the vaporizer body, causes a phase change of the liquid precursor into a vapor output. Delivery of the vapor outlet occurs along at least one high conductance run/vent valve located downstream from the vaporizing body, typically built into the vaporizer manifold architecture, and provides for metering of the vapor into a remote process chamber.

### CROSS REFERENCE TO CORRESPONDING APPLICATIONS

The present application claims the priority of U.S. Provisional Application Ser. No. 60/774,318, filed Feb. 17, 2006, and entitled Direct Liquid Injector Device.

### BACKGROUND OF THE INVENTION

1. Field of the Invention

The present invention in general relates to precursor injection in a semiconductor processing apparatus and, in particular, to a liquid precursor or precursor liquid solution injector for application in atomic layer deposition (ALD) of such as silicon wafers contained within an associated processing chamber

2. Description of the Prior Art

Atomic layer deposition (ALD) processing is exemplified by repeated, alternating exposure of a substrate to one or more separate gas phase chemical precursors/reactants. Many of the precursors in use now and on the horizon exist in liquid or solid form only. A physical property that many of these precursors have in common is a low vapor pressure, such that supplying gas concentrations large enough to sufficiently process a device wafer can not be accommodated by relying on the room temperature equilibrium gas phase of the material. External energy must be applied to cause a phase change of the material into the gas(vapor) phase to provide sufficient concentration for processing. This can be done by heating in the liquid state and using the bubbling method. But there are limitations as to how hot the system can be elevated for there are other components (typically) within the chemical delivery system, including the chemical itself that have temperature limits which they should not exceed. Therefore, in order to produce sufficiently concentrated gases from these low vapor pressure materials, another method to vaporize the liquid is used, sometimes referred to as direct liquid injection. There are many such systems available in the marketplace, but most of the systems have been developed for continuous, sustained operation as needed in CVD. A few systems are designed such that short pulses (doses) can be used in ALD, but still have caveats as to their integration. Due to the small dose requirements of ALD, and the desire for the dose output by the system to mimic the control signal being provided in real time without delay, the following list of features needs to be addressed for optimum performance:
Limited heating of the liquid precursor at the metering valve (phase change valve) to prevent decomposition of the chemical which may be consumed at a very slow rate due to the small dose nature of the process
Limited volume within the metering valve, seat to seat, to prevent valve pumping of the liquid
Limited post metering valve surface contact of the liquid prior to vaporization (minimize surface transport of liquid post valve)
Large conductance of the device to allow lowest possible pressure, created by process chamber pump, to exist at the metering (phase change) valve
Absence of changes in direction of liquid as it is transported towards the vaporizer, which can cause liquid to leave carrier gas stream and adhere to conduit boundary surfaces

As stated before, there are many available systems that are offered for vaporization of liquid precursors that might be incorporated into an ALD system, but every one of these systems are all different in design, share no common footprint, and are stand-alone components. This can be a challenge to integrate into a system that requires upstream and downstream valving, manifolding, monitoring, etc, all the while maintaining heating on the entire component assembly to prevent condensation of the vapor on the conduit surfaces prior to the process chamber.

Due to the exotic nature of the precursors, many are quite expensive to purchase, therefore it is quite desirable to minimize waste. Wile a run/vent strategy is typically used to deliver the dose by providing

a) a first path to the foreline to establish/stabilize the desired concentration and flow

b) a second path to the chamber for a given time to deliver the dose, then

c) routed back to the first path, to the foreline, it is desirable to minimize waste to the foreline, and suspend any consumption where possible between doses.

Thus, there exists a need for a precursor injector having the aforementioned attributes. Additionally, an injector is needed that limits surface contact, transport time, residual liquid stores, heating of the precursor, and offering a high conductance path to the process chamber.

### SUMMARY OF THE PRESENT INVENTION

The present invention discloses a device for mixing, vaporizing and communicating a precursor element in a highly conductive fashion to a remote processing environment. In particular, the present invention is particularly adapted for atomic layer deposition (ALD) or chemical vapor deposition (CVD) techniques associated with such as a silicon wafer processing operation.

A pallet base or other suitable support structure is provided and upon which a supply meter is secured for admitting a precursor liquid according to an associated pressure. A piezo controlled valve communicates with the supply meter for controlling the precursor liquid flow into a mixing manifold. A vaporizer component manifold is provided in cooperation with a carrier gas supply and provides a carrier gas for contemporaneous delivery into the mixing manifold;

Additional features include a vaporizing component having at least a heating element in communication with the mixing manifold and, in cooperation with a mixing material provided in the vaporizer body, causing a phase change of the liquid precursor into a vapor output. Delivery of the vapor outlet along at least one high conductance run/vent valve pair located downstream from the vaporizing body, and typically built into the vaporizer component manifold architecture, provides for metering into a remote process chamber.

Additional features include the provision of at least one base manifold in communication with the vaporizer component manifold for delivery of the vapor. Multiple base manifolds may be provided in communication with the vaporizer component manifold, at least one base manifold further operating as a diluted gas inlet line for further admixing the vapor.

A secondary heating element is provided in communication with the carrier gas supply prior to delivery to the mixing manifold. The heating elements each further may include electrical coil resistance heaters associated with cavities through which at least one of the carrier gas and pre-vaporous precursor/gas admixture passes.

A vaporizer manifold may also be provided in cooperation with the bubbler manifold for use with lower vapor pressure precursors. At least one pair, and typically a plurality of pairs formed in banks, of run/vent valves are mounted to the component manifold (or optional bubbler manifold) in communicating with the downstream location from the vaporizing body.

Additional features associated with the mixing manifold include it having a specified shape and size and further comprising an annular shaped pathway which communicates the liquid precursor with a likewise circular shaped and mating configuration associated with a crossover manifold, the annular shaping of a cooperating gap created therebetween permitting carrier gas to enter and sweep the liquid into the mixing material including a heated frit located below, and without touching surrounding walls associated with said vaporizing component. The crossover manifold may likewise incorporate a lengthwise path extending to the annular shaped pathway communicating the carrier gas inlet.

A further disclosed variant of the invention may include dual liquid injection supply meters, piezo valves and bubbler manifolds for admixing and vaporizing at least one specific liquid precursor (or a pair of distinct precursor's). According to this variant a dual outlet, three base manifold is mounted and which exhibits discrete outlets for two species of vapor created, with a common foreline connection.

### BRIEF DESCRIPTION OF THE DRAWINGS

Reference will now be made to the attached drawings, when read in combination with the following detailed description, wherein like reference numerals refer to like parts throughout the several views, and in which:

FIG. 1 is a perspective view of a single direct liquid injection DLI) device according to a first variant of the present inventions, and such as which can be incorporated into an atomic layer deposition (ALD) process associated with silicon wafer production;

FIG. 2 is a cross sectional illustration of the DLI device according to FIG. 1 and illustrating such features as manifold configuration for providing carrier gas inlet, the carrier gas/liquid interface in communication with the piezo valve controlled liquid vaporizer, the heating element, and the high conductance path vapor outlet controlled by the pair of run/vent valves;

FIG. 3 is a sectional perspective of the piezo controlled vaporizer component shown in FIG. 2;

FIG. 3A is a cutaway sectional perspective of the vaporizer component shown in FIG. 3;

FIG. 3B is an illustration of the piezo mixing valve assembled to the embarkation plate;

FIG. 3C is a further sectional perspective of an embarkation manifold component associated with the carrier annular region surrounding the liquid inlet port;

FIG. 3D is a cutaway sectional view of FIG. 3C;

FIG. 3E is a sectional perspective of the crossover manifold shown in FIG. 1 and in underlying communication with the inlet component of FIG. 3C;

FIG. 3F is a cutaway perspective of the crossover manifold shown in FIG. 3E

FIG. 4 is a perspective view of a vaporizer component base manifold illustrated in FIG. 1;

FIG. 4A is a cutaway sectional perspective of the manifold shown in FIG. 4;

FIG. 5 is a perspective view of a version of a bubbler component manifold;

FIG. 5A is a cutaway sectional perspective of the component manifold shown in FIG. 5;

FIG. 6 is a perspective view of the vaporizer component manifold shown in FIG. 1;

FIG. 6A is a cutaway sectional perspective of the vaporizer manifold shown in FIG. 6;

FIG. 7 is an assembled view of the heated cavity subassembly for assisting in phase change of the carrier gas/low vapor pressure liquid precursor mixture into the high conductance outlet vapor;

FIG. 7A is an exploded view of the heater subassembly of FIG. 7;

FIG. 8 is a perspective illustration of a further variant of a single direct liquid injection (DLI) device, illustrating a single bubbler component manifold installed and in joint communication with an associated pair of base manifolds;

FIG. 9 is a perspective illustration of a dual direct liquid injection (DLI) device according to a further variant of the present inventions;

FIG. 10 is a rotated perspective illustration of the device shown in FIG. 9;

FIG. 11 is a perspective illustration of the dual outlet manifold block according to a further sub-variant of the invention such as shown in FIG. 9 and illustrating both a central common path to an associated foreline, as well as first and second dilution inlets for associated first and second species of liquid injected precursor;

FIG. 11A is a cross sectional cutaway of the manifold block shown in FIG. 11;

FIG. 12 is a perspective illustration of a dual outlet, three base manifold DLI according to a yet further variant of the present inventions; and

FIG. 13 is a cross sectional view of FIG. 12 and showing the bubbler manifolds arranged atop the three base manifold configuration of FIG. 12.

### DETAILED DESCRIPTION OF THE PREFERRED EMBODIMENTS

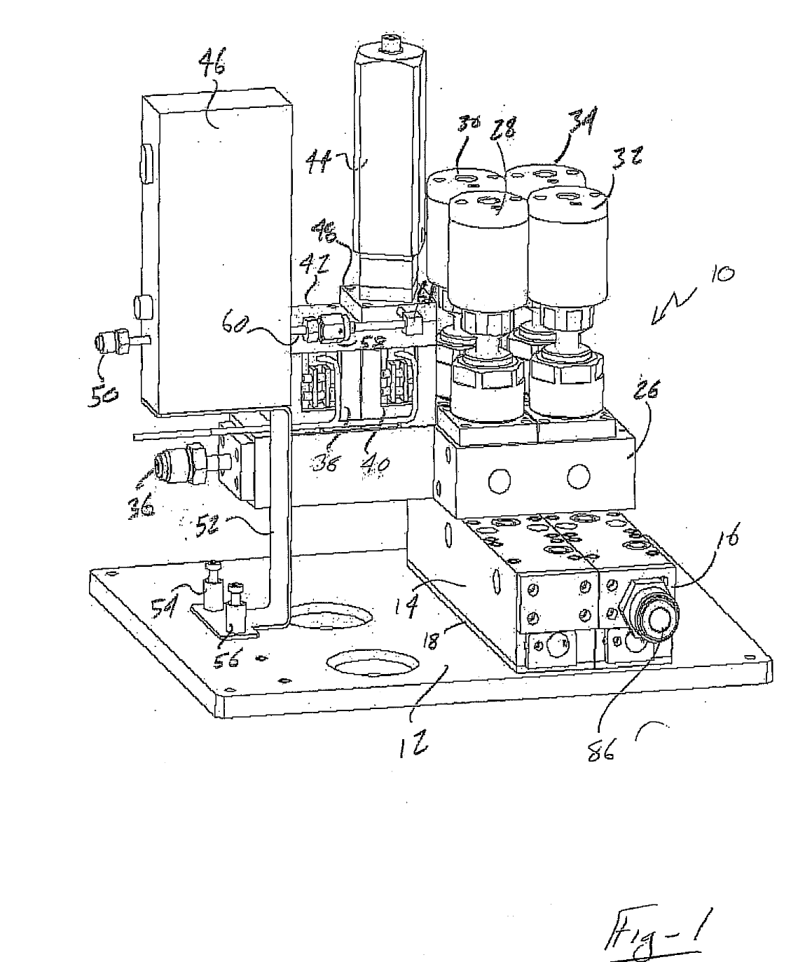

Referring now to FIG. 1, a perspective view is generally shown at 10 of a single direct liquid injection ELI) device according to a first variant of the present inventions. As previously described, the present invention, the DLI device is typically incorporated into such as an atomic layer deposition (ALD) process associated with silicon wafer production, and such as which can be carried out within a semiconductor processing chamber (not shown). As will also subsequently described in additional detail, the DLI vaporizer assembly can further be utilized in other applications, not limited to chemical vapor deposition (CVD), high quality film formation, and other critical semiconductor and other related industrial applications.

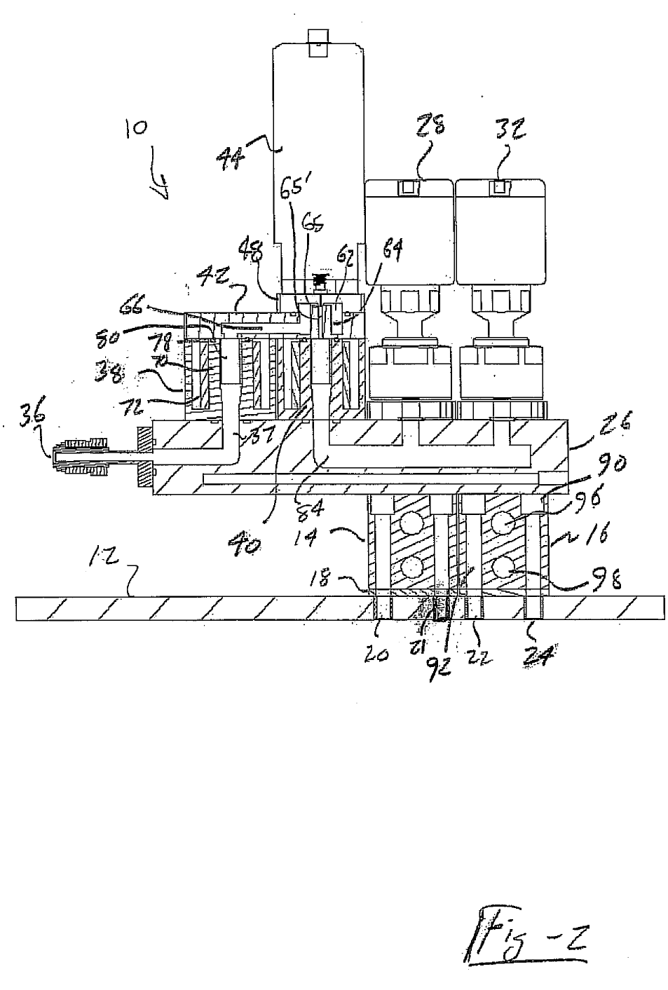

Viewing the cross sectional cutaway of FIG. 2 in cooperation with FIG. 1, the device 10 is constructed upon a pallet base 12 having a generally planar configuration and capable of supporting the various components which provide for vaporization and high conductance delivery of the liquid precursor. These components are generally referenced here, primarily as to their structural interrelationships relative to one another, and will be subsequently described in additional detail with reference to succeeding illustrations.

The above said, a pair of base manifolds 14 and 16 (typically a machined aluminum) are provided and which are supported upon a ceramic insulating layer 18, in turn bolted or otherwise secured to a location of the base 12 (see fasteners 20, 21, 22 and 24 in the cutaway of FIG. 2). A vaporizer component manifold is illustrated at 26 and communicates with a plurality of high conductance valves, see as shown by pairs of run valves 34 &32 and vent valves 28 &30. Carrier gas inlet is further illustrated at 36 associated with a remote end of the vaporizer component manifold 26 and communicates to a top facing outlet 37 in the manifold 26, and as will be further described. At least one high conductance run/vent valve, as again illustrated at 30 & 34, is provided downstream from the vaporizing body to meter the carrier gas/heated precursor mixture into a process chamber. Preferably, the conduit between the vaporizer body and the processing chamber is of minimal length and angular deflections. While the conduit is depicted in the appended figures as extending orthogonal to the base of the vaporizer body, it is appreciated that a conduit is readily extended at a variety of angles, including downward and generally parallel to the axis of the vaporizing body and preferably, concentric with the vaporizing body axis.

Yet additional components of the device include the pair of heating ring array assemblies, see at 38 and 40, also termed heated cavities, these functioning to preheat both the gas introduced through inlet 36 (at 38) as well as the gas/liquid interface (at 40) during the vaporization procedure performed on the liquid/gaseous mixture. A cross over manifold is shown at 42 and supports thereupon a piezo mixing valve assembly 44, this in turn operating to control liquid flow introduced through a liquid supply control device 46 (such as a liquid mass flow meter), via associated embarkation manifold 48.

A liquid supply inlet 50 is illustrated in cooperation with the selected liquid precursor and the precursor liquid mass flow meter 46 is supported upon a substantially U-shaped bracket (see at 52 in FIG. 1), in turn mounted upon the pallet base 12 (see further mounting components 54 and 56 engaging an angled bottom portion of the bracket 52 and opposite an upper level edge surface upon which is supported the component 46). The liquid mass flow meter 46 further operates to monitor an upstream liquid flow rate associated with the liquid precursor and, concurrent with the regulating aspects of the piezo mixing valve assembly 44, admixes the carrier gas (again via inlet 36) within the cross over manifold 42, from which it then is presented to a vaporizer heated frit, not shown but which is understood to be located in the second heated cavity 40 which is in direct communication with the crossover manifold outlet.

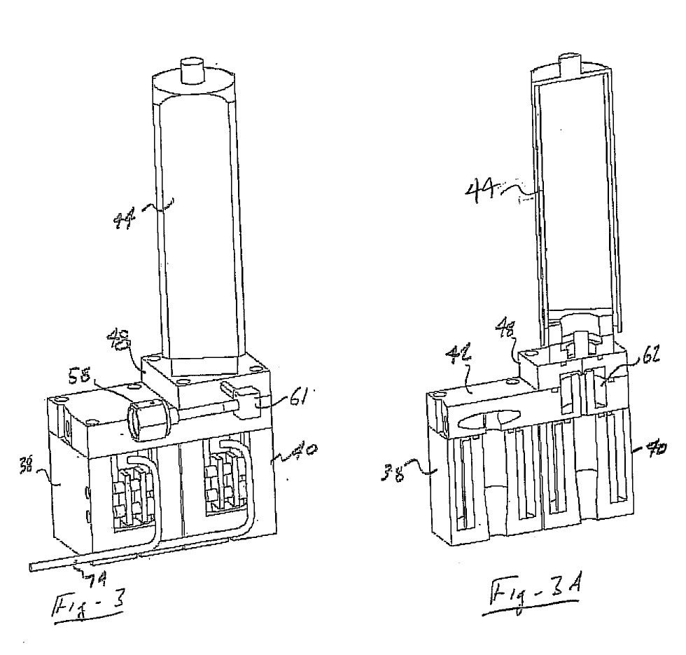

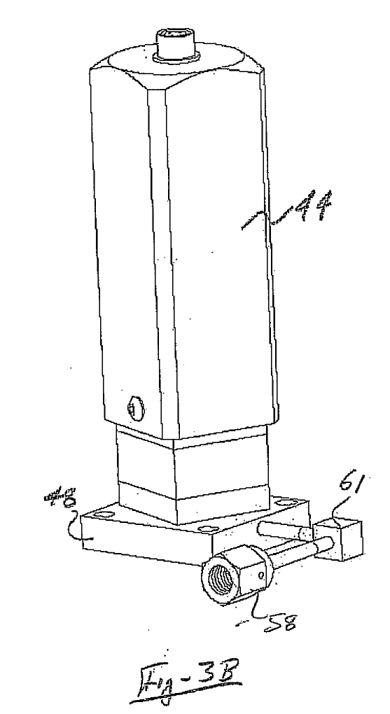

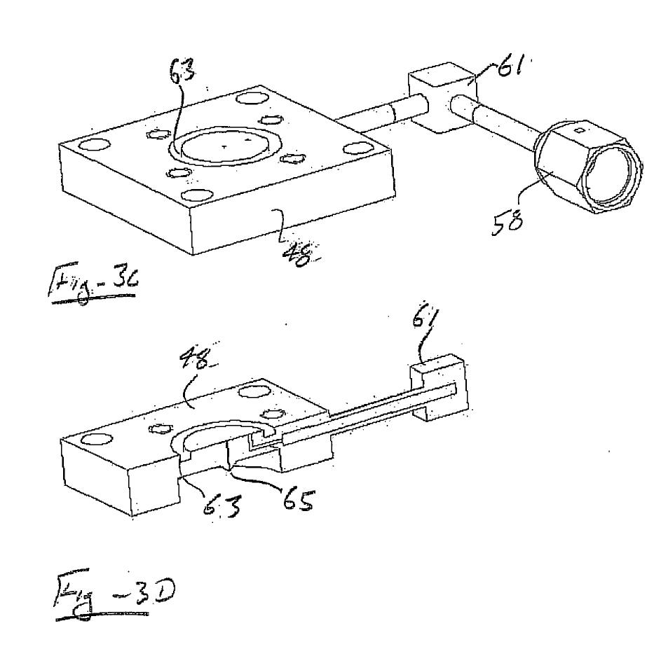

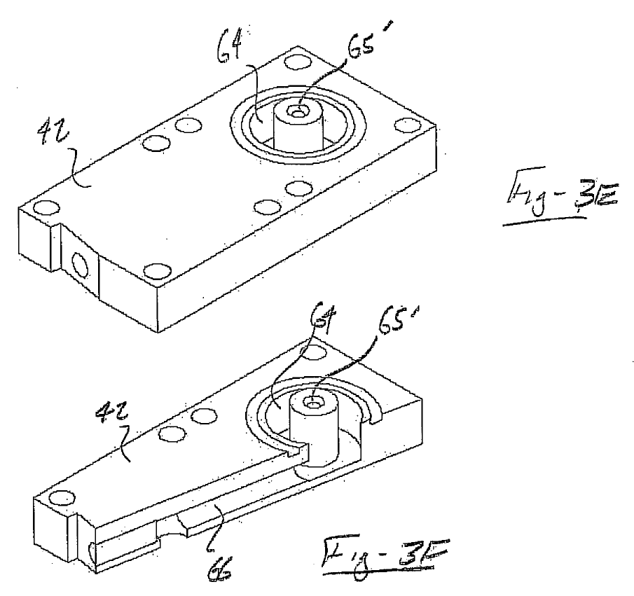

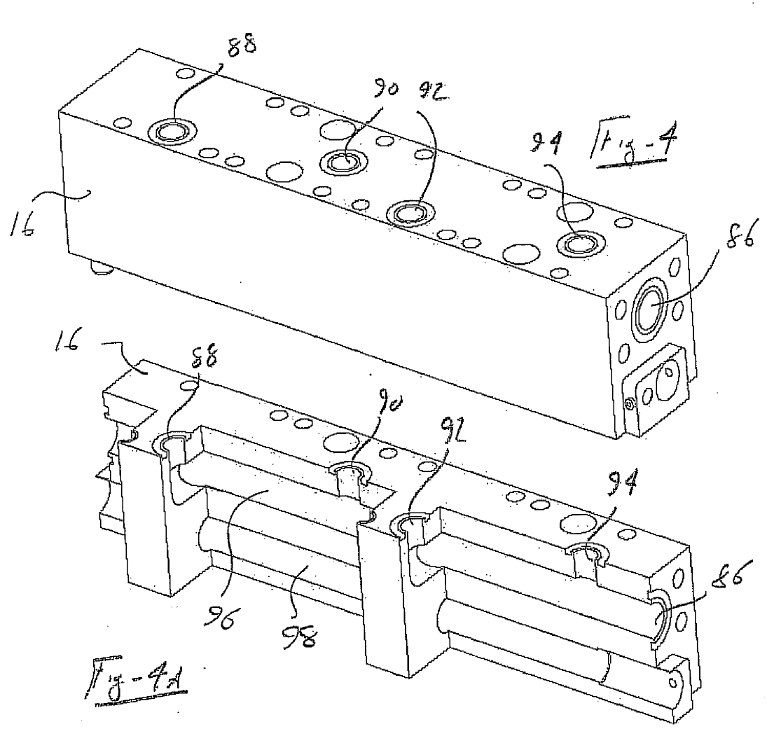

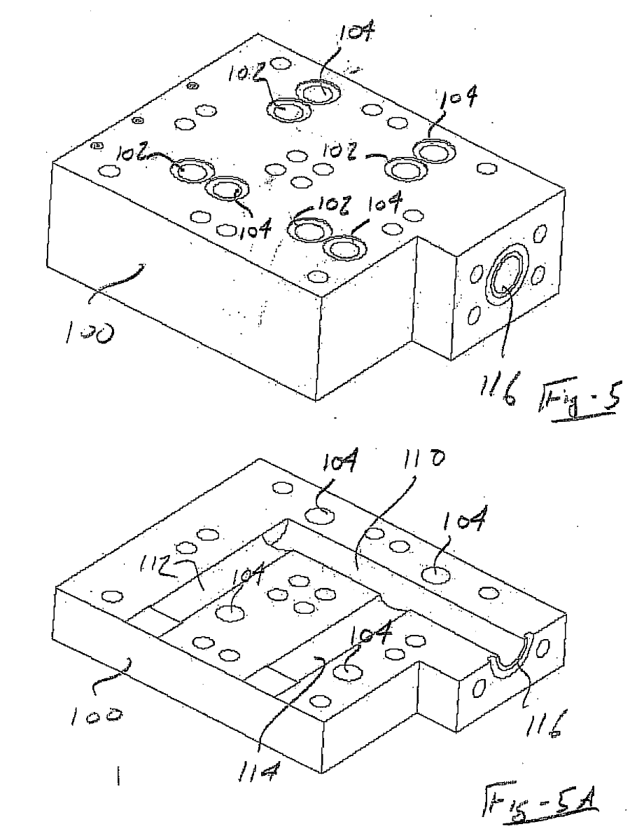

Addressing again the cross sectional illustration of the DLI device according to FIG. 2, and in cooperation with the succeeding illustrations of FIGS. 3-3F, an attachable coupling 58, typically a threadably rotatable and locking bolt, is provided for communicating the liquid precursor introduced from the supply control device 46 by an outlet line 60 (see FIG. 1). An L-shaped fluid delivery line, see as generally referenced at 61 introduces the liquid precursor to the manifold component 48 associated with the piezo controlled valve 44. In particular, and as best shown in FIGS. 3C and 3D, the manifold component 48 exhibits an annular or circular shaped pathway which communicates the delivered liquid precursor (see as best shown in cutaway of FIG. 3C) with a likewise circular shaped and mating configuration associated with the crossover manifold 42 (see further this mating arrangement in the cutaway of FIG. 3A). The annular region is referenced as adjoining annular sections associated with the mixing manifold, at 62, and the crossover manifold, at 64, in the cutaway of FIG. 3A and is completely formed by the assembly of crossover to embarkation plates. Liquid exits the tip of conical outlet, admixes with concentric carrier gas flow, and is transported down the interior concentric path to the heated frit below. As further shown in FIGS. 3C and 3D, an O-ring groove 63 is provided. The liquid gas mixture exits the conical tip 65 (see FIG. 3D cutaway) into the horizontal annular region (see at 65′ in FIG. 3E), getting swept with the carrier into the central passage as shown with reference to the location established between the DLI introduction and crossover manifolds.

The embarkation manifold 48 is an all metal seat and seal design, with the O-ring groove on the top of the embarkation plate (the plate in which the liquid is routed from the flow controller into the valve set area) designed for an all metal seal. The bottom of the valve is essentially a flat surface of very high quality surface finish. It bolts separately to the top of the embarkation plate, forming the embarkation valve assembly. The embarkation plate according to one desired design further exhibits two small holes that communicate to the top of the embarkation plate, such that this upper surface of the embarkation plate is essentially the valve seat, being a extremely smooth surface finish that the flat valve bottom mates to. The liquid traverses the region between the two mating surfaces. Unenergized, the piezo valve is in a contracted state (see again cutaway of FIG. 2), and the liquid can flow out through the center hole, on to the conical tip in the annular region formed between the bottom of the embarkation plate and the top of the crossover manifold, where it is picked up by the carrier gas and transported down into the vaporizer frit. As the valve is energized, in this case, the crystal changes in length (grows), thereby causing deflection in the bottom of the valve which seals off the path between the two small holes, providing a method of regulating the liquid flow rate.

The annular shaping of the cooperating gap permits the carrier gas to enter and sweep the liquid into the heated frit below, and without touching the surrounding walls. The crossover manifold 42 likewise incorporates a lengthwise path 66 extending to the circular shaped and mating/mixing locations 62 and 64, this path 66 communicating with the carrier gas inlet 36 via the coiled heating cavity 38 which is provided for increasing the inlet temperature of the selected carrier gas to a suitable degree at the location in which it admixes with the liquid precursor and prior to the delivery to the secondary heater 40. The secondary heater 40 further operates to supply the thermal energy necessary to assist in the phase change of the typically lower pressure liquid/carrier gas admixture exiting the crossover manifold vapor outlet.

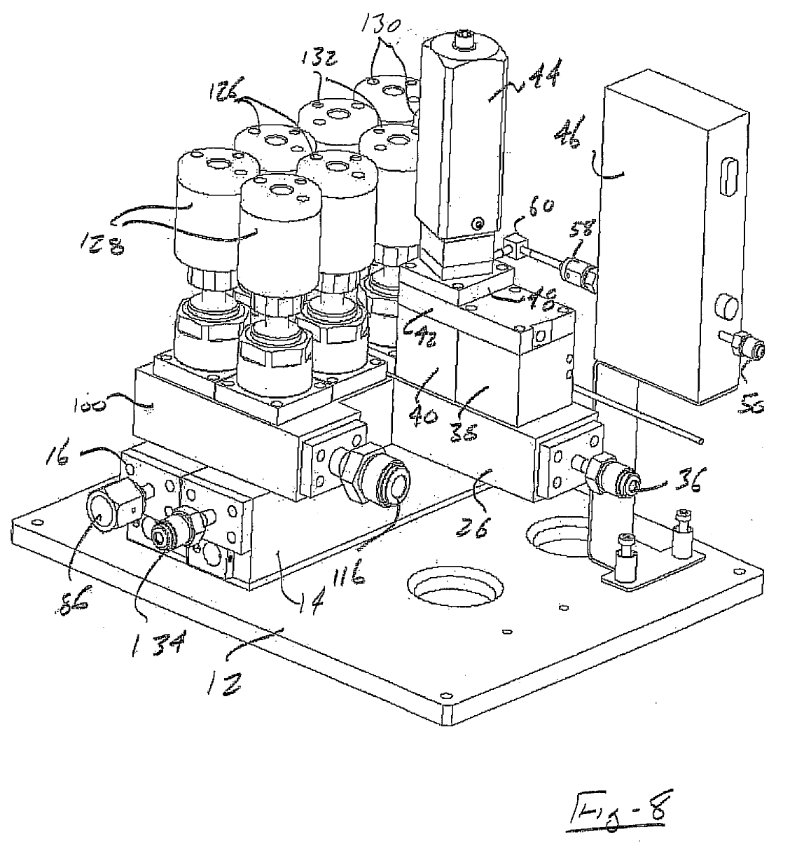

A coarse filter matrix provides surface area within the vaporizer body 40 to allow for thermal transfer between the heating element and the precursor within the vaporizer body. Filter matrix material is typically selected to be chemically inert toward the precursor under the conditions within the vaporizer body. Matrix materials illustratively include fused silica, alumina (including a commercially known product called Duocell® which is an aluminum foam type of material), graphite, and metal flake. It is appreciated that in some instances one wishes to chemically transform a precursor into an active, unstable species prior to introduction into a processing chamber and a catalyst is optionally placed within the filter matrix to induce the desired precursor chemical transformation. In one application, the coarse frit material (as will be illustrated with subsequent reference to FIG. 7A) may be used to provide additional surface area for evaporation within the secondary heating chamber 40, but is intended to be sufficiently coarse such that the bulk of the driving energy for the phase change is due to the changes in pressure occurring at the associated valve outlet. A fine filter matrix, positioned in the upstream heated cavity 38, may also be provided for improved heating of the carrier gas prior to entering the crossover manifold.

In addition to the coiled nozzle heating elements 38/40, provisions may be made in the bubbler, vaporizer and base manifolds to accept cartridge heaters and the like to maintain a desired temperature for the entire assembly, in particular to prevent condensation. Use of cartridge heaters in drilled holes within these components further makes heating more easily accomplished, this being more difficult to accomplish when using discrete components.

Referencing further FIGS. 7 and 7A, both assembled and exploded views are illustrated of a selected heated cavity subassembly. As previously referenced for example at 38, a three dimensional shaped and heated cavity block is provided and exhibits a recessed circular configuration within its top surface, see annular shaped recess 68 within which is supported a substantially extending central column 70. An electrical resistance coil heater (or nozzle heater) is provided as a generally cylindrical shaped sleeve 72 which matingly fits over the annular exterior surface of the column 70 associated with the outer cavity block. A highly conductive coil element contained within the heated cavity is supplied by regular electrical leadwires 74 and which mate to resistance wires embedded within the coil assembly, i.e. generally as shown at 75 in FIG. 7A, and is integrally connected with a surface of the inner insertable sleeve 72 (see at location 76) and conveys such as an electrically generated heat source (not shown but which in one variant can be provided via a highly conductive resistance cable) to a central passageway 78 through which the carrier gas passes.

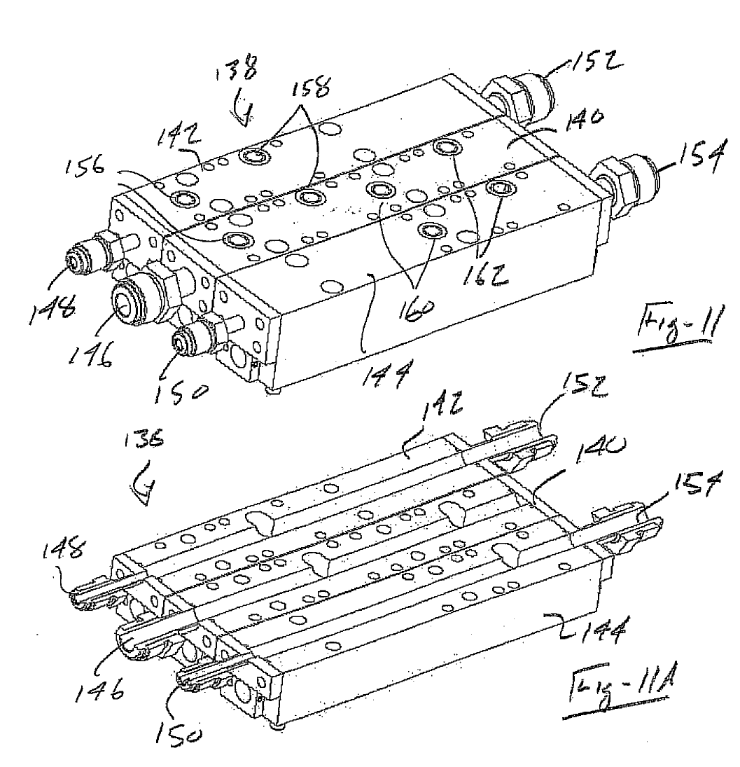

Further referencing the exploded view of FIG. 7A, an O-ring seal 80 may be provided to complete the assembly and communicate the heated gas via the crossover manifold pathway 66. Frit element 82 slides down into the column 70, such that either a fine or coarse frit can be installed depending on the upstream/downstream location. The secondary heater assembly 40 is likewise constructed and operates in substantially the same fashion in order to assist in the phase change of the low pressure carrier gas/precursor liquid to the outlet vapor. The vapor exiting the secondary heater, see at 84 in FIG. 2, is communicated via high conductance paths to the associated run 32 & 34 and vent 28 & 30 valves to either base-manifold 14/16, and henceforth to either the wafer processing chamber (not shown) or to the foreline via arrangement 136, shown in FIG. 10.

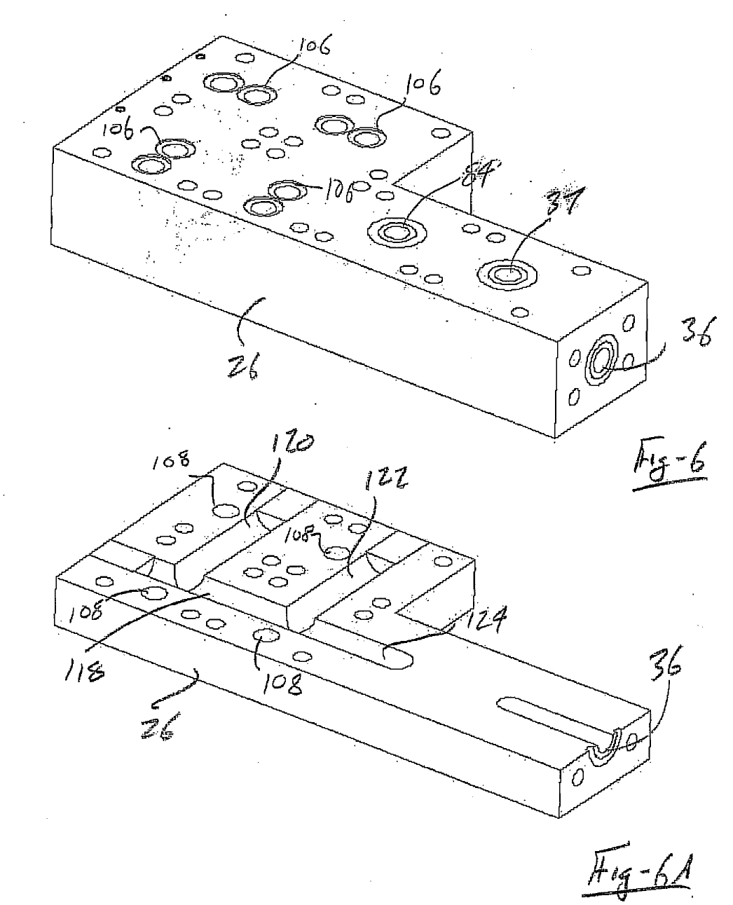

Referring now to FIGS. 4 and 4B, additional explanation will be made as to the features of the base block manifolds 14 and 16 shown in FIG. 1. In particular, a first of the manifolds, e.g. that shown at 16 and which is represented in FIG. 4, may include an inlet line (as previously mentioned but not shown) and which may constitute such as a diluted and optionally heated argon gas or the like. Two base manifolds are necessary, as one provides the path to chamber, and the other to the foreline. The blocks illustrated support 2 vaporizer component manifolds for 2 species, it being further understood that, according to the variant of FIG. 1, the unused inlets can be capped-off or the blocks shortened as necessary for application to a single DLI channel variant.

In a typical application, a pair of such blocks 14 and 16 are utilized in side-by-side fashion and can use a common outlet for the process chamber for the two different species. In this application, one block (e.g. either 14 or 16) would route each gas via two parallel valves (a plurality of which are referenced by outlets 88, 90, 92 and 94 in FIGS. 4 and 4A communicating from longitudinal and lengthwise extending pathway 96 (FIG. 4A). Passages 98 extending one from each side of the block 16 are not in communication, and define locations where optional cartridge heaters (not shown) are installed for heating, it again being understood that passages 98 may be selectively capped based upon the combinations of heated inlet gas(es) or vaporized precursor(s) employed.

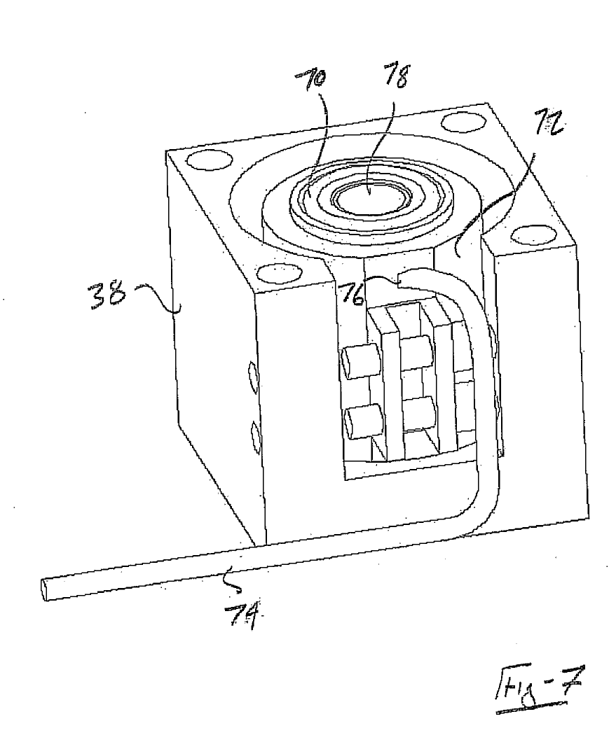

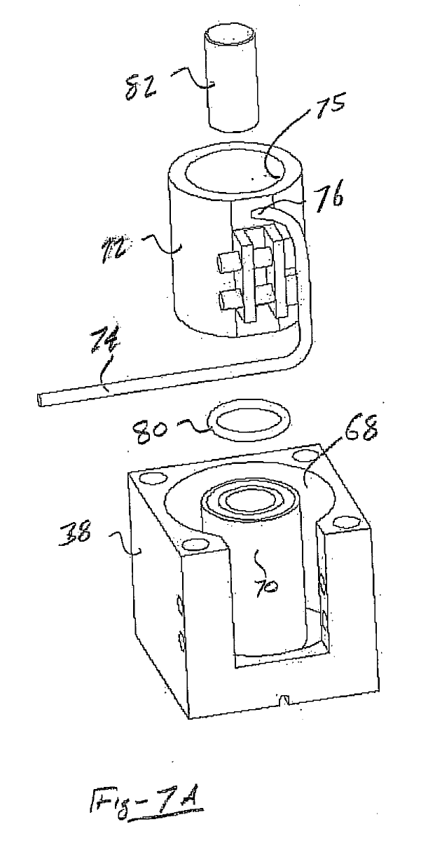

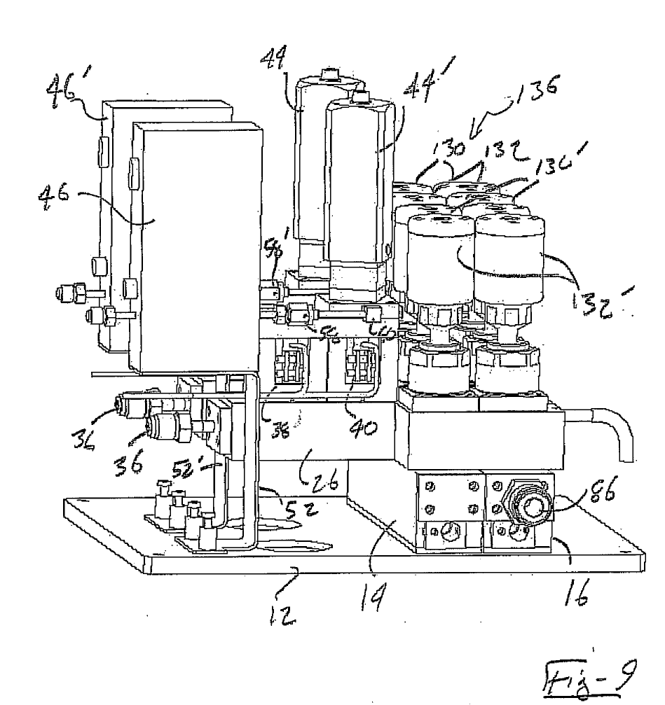

Referring to FIGS. 5 and 5A, a bubbler component manifold 100 is provided and which cooperates with the vaporizer component manifold, previously identified at 26 (FIGS. 6 and 6A), with particular reference to the alternate single DLI arrangement set forth in FIG. 8. Both the bubbler 100 and vaporizer component 26 manifolds in FIGS. 5 and 6 utilize two pairs of valves, see receiving aperture locations at 102 & 104 for bubbler component manifold 100 and at 106 & 108 for vaporizer component manifold 26, and in order to route gases to the underlying base manifolds (14 and 16), and to either the chamber (again not shown) or the foreline pathways (for example via inlet 86). Longitudinal passageways are illustrated, as to the bubbler manifold 100 further at 110 with feeder passageways 112 and 114 (FIG. 5A) to communicate the pairs valve inlets 102 and 104 to an outlet location (not shown in this view). Further illustrated at 116 is the bubbleer inlet to the block.

The vapor for both types of blocks is presented to the valves via four large passages that are located in the center of each smaller 4 bolt hole array. As is shown, the outlet from the valve is located off center, towards one pair of bolt holes. The outlets then communicate with the base manifolds below. Because of the complexity in getting the downward paths to the base manifolds, one set of valves is oriented in one direction, while the other set has to be oriented in another direction. It is further noted that both run valves use a valve of both mounting orientations, the same for the foreline pair. Additional interior passageways for the vaporizer component manifold 26 are shown at 118 with feeder passageways 120 and 122 (FIG. 6A) in order to communicate the pairs of valve inlets 106 and 108 to an associated outlet in communication with the heater/vaporization stage 40 previously described. Also referenced at 124 is the inlet to this component, from the vaporizer, it also being understood that the vapor exits through the same off-center holes which are in communication with the valves.

As understood, the vaporizer/bubbler manifold components (26 and 100) can be used interchangeably, and determined by the needs of the precursors employed, as well as to the number of precursors utilized. As with the base manifolds 14 and 16, the vaporizer/bubbler manifolds 26 and 100 are fabricated of a suitable aluminum, steel or machine stock material with drilled passages which then have a welded-in plug so as to form gas-tight internal passages.

Pairs of high conductance valves are utilized to in order to create the greatest conductance path possible back towards the point of vaporization, being either the vaporizing frit area or in the case of a bubbler, to the bubbler canister headspace. These are shown in the example of FIG. 8 as pairs 126 and 128 associated with locations 102 (passages from intersecting interior of block and going up to valve inlet) and 104 (passages going through block from the valve exiting the base manifold below) of the bubbler manifold 100 and further at 130 and 132 associated with locations 106 (passages from intersecting interior of block and going up to valve inlet) and 108 (passages going through block from the valve exiting the base manifold below) of vaporizer manifold 26. It is further noted that the passages between the two manifolds 26 and 100 are different given the applications of the bubbler manifolds in different directions upon the base manifolds 14 and 16. The large port diameters of the associated high conductance valves, these further again illustrated in the variant of FIG. 8, are important, as the valves tend to be the limiting factor in gas path conductance, and since a typical valve seat only travels very incrementally when operating. Although not shown, it is further understood that heater cables may connect to either of the vaporizer manifold 26 and bubbler manifold 100 and in order to assist in heating either or both of the carrier gases and/or the liquid precursors associated with the vaporization and subsequent ALD procedure.

Referencing again FIG. 8, a perspective illustration of the further variant of a single direct liquid injection (DLI) device is again shown and illustrating the single bubbler block 100 in cooperation with the vaporizer manifold block 26 in joint communication with an associated pair of base manifolds 14 and 16. Many of the identical components associated with the initial variant description of FIG. 1 are repeated in the illustration of FIG. 8. For example base manifold 16 illustrates a dilution gas (e.g. Argon) inlet 86, and a further inlet, at 134, is shown in relation to corresponding base manifold 14 for connection by an associated foreline (not shown) and such as which may extend to the processing cabinet.

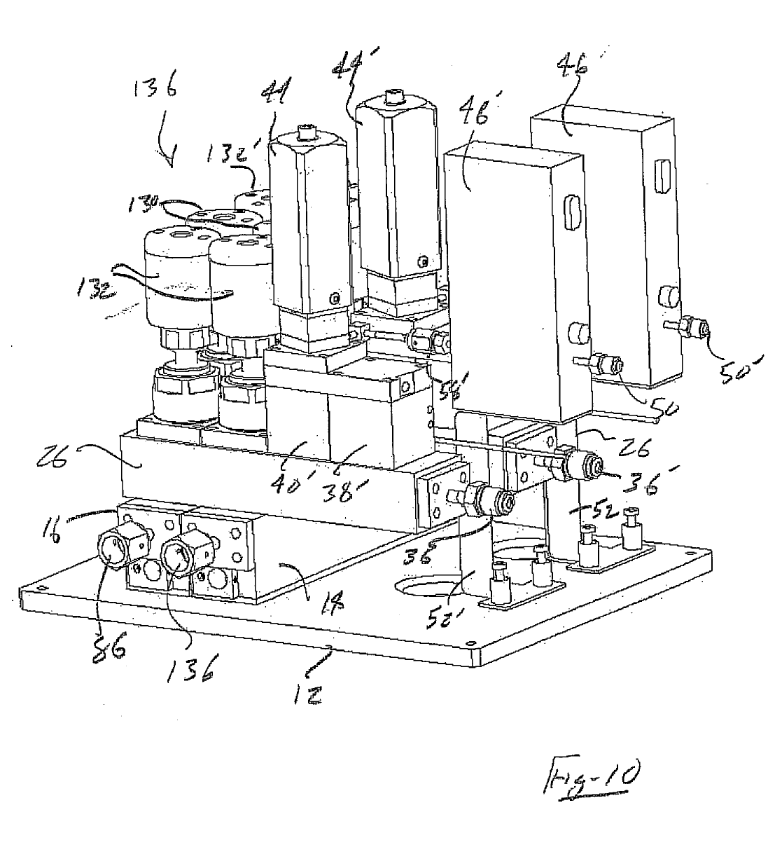

Referring now to FIGS. 9 and 10, first and second rotated perspective illustrations are shown at 136 of a dual direct liquid injection (DLI) device according to a further variant of the present invention. Identical components are likewise number in the variant of FIG. 9 in duplicating fashion (e.g. fluid inlet and regulating manifold is both referenced again at 46 as well as at 46′ to reference two such items in use with the illustrated variant) and which operates off the same concept as that previously described in reference to the single DLI variant of FIG. 1, with the exception that the components associated with the DLI injection of precursor are modified in order to facilitate vaporization of two DLI liquids. It is further noted that the dual DLI variant of FIG. 9 differs from the subvariant of the single DLI device in FIG. 8, in that the bubbler manifold 100 is substituted for a duplicate vaporizer manifold 26.

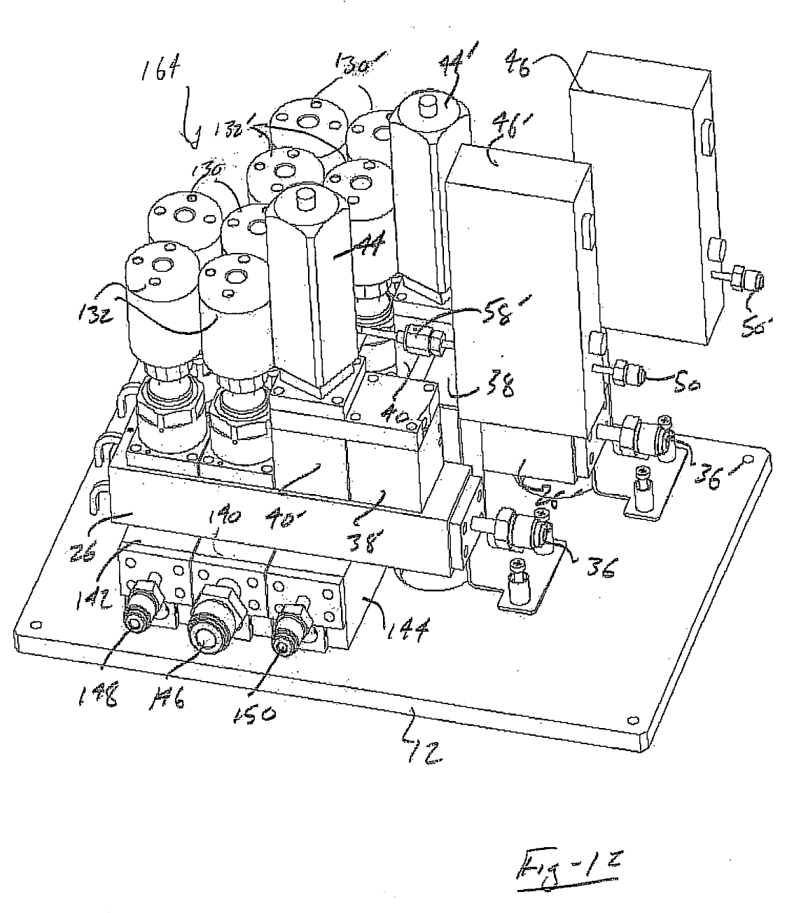

Referring to FIGS. 11 and 11A, perspective and cutaway illustrations are shown at 138 of a variant of dual outlet manifold block according to a further sub-variant of the invention such as shown in FIG. 9 (this substituting for the pair of base blocks shown at 14 and 16). The modified base block design includes a standard base manifold (central) block 140 in communication with a pair of laterally projecting blocks 142 and 144 arranged on opposite sides thereof. The central block 140 exhibits a common foreline path, at 146 (it being understood that the outlet can be likewise located at an opposite end and a purge gas supplied if desired). The secondary blocks 142 and 144 her respectively present dilution gas inlets 148 and 150, opposite outlet ends of which (at 152 and 154) respectively communicating the eventual first and second vaporized precursor species into the processing chamber (such as at which the ADL, CVD or desired processing operation is performed). Further illustrated at 156 and 158 (see FIG. 11) are species #1 inlets to the blocks 140 and 142, whereas illustrated at 160 and 162 are species #2 inlets to the blocks 140 and 144.

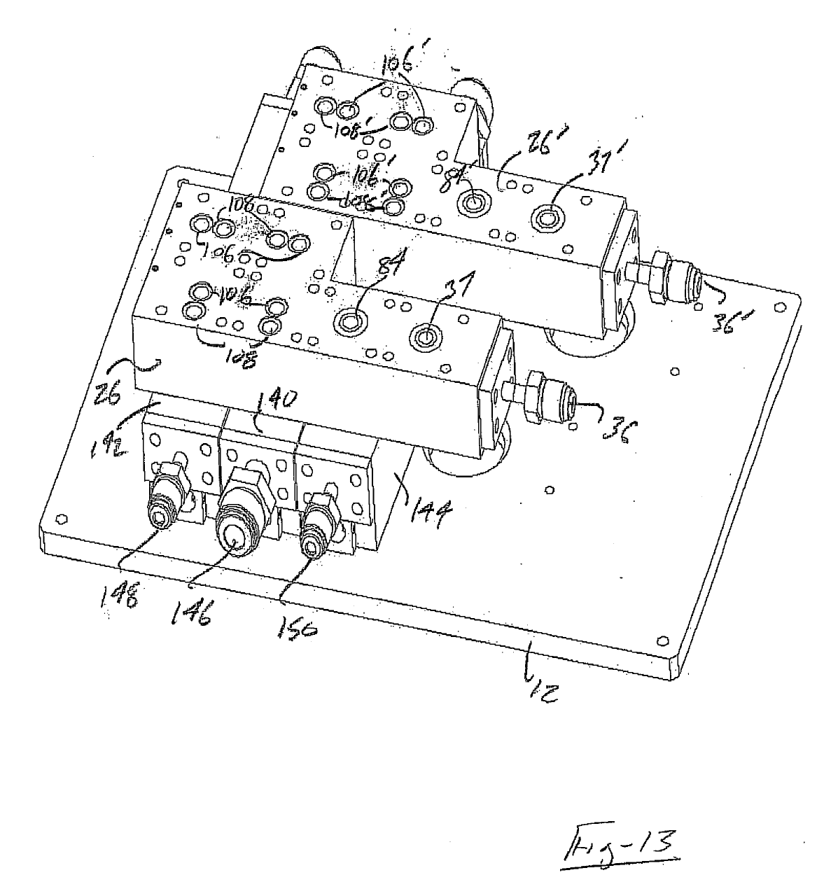

FIG. 12 is a perspective illustration, at 164, of a dual outlet, three base manifold DLI according to a yet further variant of the present invention. In this variant, the base manifolds in the dual DLI apparatus are modified to include the sub variant of FIGS. 11 and 11A and in order to permit the staggered installation of vaporizer and vapor block assembly. This, as previously described with reference to FIG. 11A, permits the discrete outlets for the two species of vapor created, with a common foreline connection. In such an application, a vent-run-vent type of gas delivery is employed, without the concern as to whether the two precursors mix in the common foreline (again at 146). Additional applications contemplate utilizing the same precursor in each DLI supply, and depending upon the amount of precursor needed and the limits associated with an ortherwise single delivery line in creating the desired quantity of vapor. In such an application, an increase in vapor created will often result in an attendant increase in pressure, at which point condensation may occur, and the further ability to provide two alternating vapor generators may be beneficial if they do not impact one another. Referencing finally FIG. 13, a further cross sectional view of FIG. 12 is shown of the vaporizer manifolds 26 and 26′ arranged atop the three base manifold configuration of FIG. 12 and again illustrating the staggered nature of the manifolds supported upon the pallet base 12.

Additional considerations to be noted with respect to the present designs include the vaporizer per se being contained within the components of two heated cavities, the crossover manifold, and the embarkation valve assembly. These components can and do share the same mounting hole patterns as the modular surface mount valves used to direct the vapor flow. The vaporizer is capable of being assembled directly on the same industry standard manifolding that the valves are, and in fact share the same mounting interface as manual valves, pneumatic valves, filters, regulators, and other components offered by many third parties, all designed for use on an industry standard platform geometry. This permits advantages in integration of the vaporizer to these other components. It also maintains the advantage of compactness in design, this being one factor in the creation of the modular surface mount method. It is also envisioned that other industry standard substrates can replace the component and base manifolds, and without departing from the scope of the invention, this factor providing a significant advantage of the present design over other competing prior designs known in the relevant industry.

With further respect to the liquid controller, the present invention contemplates the use of a digital liquid mass flow controller, and where the control valve is incorporated into the embarkation valve assembly (again at 48 in FIG. 3C), and in order to control the liquid flow rate of the liquid precursor. The mass flow controller (i.e. again at 46) is digital in construction such that, if given a setpoint, it stores the control valve applied voltage signal in memory and, when further given a memorized setpoint, jumps directly to that memorized valve voltage and starts using a PID algorithm to continuously control. This scheme provides a very quick ramp to the setpoint, and results in steady flow within a half a second of issuing that setpoint. This is a distinct advantage, for in ALD the user can leave it at a zero setpoint until just before need to deliver the desired precursor chemical, resulting in a minimal waste to vent. Use of the control device (e.g. control valve) may incorporate both analog and digital sensing and control electronics, and in addition to analog alone or digital alone. Further considerations may include eliminating the liquid flow rate control device and just use a valve, be it pneumatic, electromagnetic or piezo, with the liquid under a known pressure, the further use of the valve open time being the only variable for controlling the amount of liquid introduced into the vaporizer.

The present invention therefore has utility in the transport and delivery of precursors to a semiconductor processing chamber. The injector apparatus (see again manifold 46 and piezo controlled valve 44) is provided to limit surface contact, transport time, residual liquid stores, heating of the precursor, and offering a high conductance path to the semiconductor process chamber.

Additional features include the device optionally providing a region within the vaporizer that offers enhanced surface area for larger dissipation of the liquid for evaporation. As described, the device may also include a region for preheating the carrier gas (see again coiled heater assembly 38) and prior to entering the vaporizing region. A variant of the overall device design enables it to be integrated into existing standardized modular gas components, thereby becoming just another component on a standard platform, and leveraging on the developed heating methods for the same standardized components. The scalability of the present invention is further evident from the varying embodiments which may employ different combinations of precursor liquid(s), bubbler and/or vaporizer manifolds, and differing architecture involving the base manifold(s). The device also aims to minimize waste of precursor by utilizing fast control components in the closed loop control version to minimize run/vent requirements, and/or foregoing closed loop control altogether and operating in a lower cost open loop mode with a simpler metering (phase change) valve.

It is also appreciated that any number of mounts are operative herein. Factors associated with the choice of mount architecture and construction material include in part the vapor pressure of the precursor, precursor corrosiveness, and precursor flow rates.

Some additional attributes associated with the inventive device include:
a) Transportation of liquid from metering valve to vaporizer designed to minimize surface transport mechanism, improve response to control signal changes
b) Carrier gas provides annular sheath for transporting liquid into vaporizer
c) Carrier gas can be heated as an integral part of this device
d) Design supports closed loop control of short dose pulses with minimum waste
e) Design minimizes stagnant chemical stored at elevated temperature near metering valve
f) Small, compact design lends to installation in tight locations

Having described my invention, other and additional preferred embodiments will become apparent to those skilled in the art to which it pertains and without deviating from the scope of the appended claims:

I claim:

1. A direct liquid injector device comprising:
a carrier gas inlet;
a liquid metering valve delivering a liquid precursor into a volume of a carrier gas/liquid interface unit;
a vaporizer body receiving a mixture of the liquid precursor and a carrier gas;
a heating element in thermal contact with said vaporizer body;
a matrix material within said vaporizer body;
at least one high conductance run/vent valve located downstream from said vaporizing body for meter the mixture along a conduit for delivery into a remote process chamber.

2. The device of claim 1, wherein the volume is located above said vaporizer body.

3. The device of claim 1, wherein an annular gap allows the carrier gas to enter and sweep the liquid from the volume into said vaporizer body.

4. The device of claim 1 further comprising a carrier gas heater.

5. The device of claim 1 wherein said conduit is vertically displaced below said vaporizer body.

6. The device of claim 1 wherein said conduit is linear.

7. The device of claim 1 wherein said at least one high conductance run/vent valve further comprises at least one pair of valves.

8. The device of claim 1 wherein the carrier gas flows downward through the volume into said vaporizing body.

9. The device of claim 8 wherein said conduit extends orthogonal to a central axis of said vaporizing body.

10. The device of claim 8 wherein said conduit extends parallel to a central axis of said vaporizing body.

11. A device for mixing, vaporizing and communicating a precursor element in a highly conductive fashion to a remote processing environment, comprising:
a supply meter for admitting a precursor liquid according to an associated rate;
a control valve in communication with said supply meter for controlling said precursor liquid flow into a mixing manifold;
a vaporizer manifold in cooperation with a carrier gas supply and providing a carrier gas for contemporaneous delivery into said mixing manifold;
a vaporizing component including at least a heating element in communication with said mixing manifold and, in cooperation with a mixing material provided in said vaporizer body, causing a phase change of said liquid precursor into a vapor output; and
delivery of said vapor outlet along at least one high conductance run/vent valve located downstream from said vaporizing body for metering into a remote process chamber.

12. The device as described in claim 11, further comprising at least one base manifold in communication with said bubbler manifold for delivery of said vapor.

13. The device as described in claim 12, further comprising multiple base manifolds in communication with said bubbler manifold, at least one base manifold further comprising a diluted gas inlet line for further admixing said vapor.

14. The device as described in claim 11, further comprising a secondary heating element in communication with said carrier gas supply prior to delivery to said mixing manifold.

15. The device as described in claim 14, said heating elements each further comprising electrical coil resistance heaters associated with cavities through which at least one of said carrier gas and said pre-vaporous precursor/gas admixture passes.

16. The device as described in claim 11, further comprising a bubbler manifold provided in cooperation with said vaporizer manifold for use with lower vapor pressure precursors.

17. The device as described in claim 11, further comprising at least one pair of run/vent valves mounted to said vaporizer manifold in communicating with said downstream location from said vaporizing body.

18. The device as described in claim 11, said mixing manifold having a specified shape and size and further comprising an annular shaped pathway which communicates said liquid precursor with a likewise circular shaped and mating configuration associated with a crossover manifold, the annular shaping of a cooperating gap created therebetween permitting carrier gas to enter and sweep the liquid into said mixing material including a heated frit located below, and without touching surrounding walls associated with said vaporizing component.

19. The device as described in claim 18, further comprising said crossover manifold likewise incorporating a lengthwise path 66 extending to said annular shaped pathway communicating the carrier gas inlet.

20. The device as described in claim 11, further comprising dual liquid injection supply meters, control valves and vaporizer manifolds for admixing and vaporizing at least one specific liquid precursor.

21. The device as described in claim 20, further comprising a dual outlet, three base manifold exhibiting discrete outlets for two species of vapor created, with a common foreline connection.

22. The device as described in claim 1, said vaporizer body further comprising at least one heated cavity arranged in communication with a crossover manifold and an embarkation manifold/control valve, each of said cavity and manifolds being sized and adapted for installation upon industry standard modular surface mount substrate components.

23. The device as described in claim 11, further comprising said control valve utilizing a mechanical deformation of a piezo crystal in order to provide motion to said valve seat.

24. The device as described in claim 11, said control valve utilizing an electromagnetic force to provide motion to said valve seat.

25. The device as described in claim 11, said control valve utilizing a pneumatic actuation to provide motion to said valve seat.

26. The device as described in claim 11, said supply meter further comprising an analog electronic sensing and control design.

27. The device as described in claim 11, said supply meter further comprising a digital electronic sensing and control design

28. A device for mixing, vaporizing and communicating a precursor element in a highly conductive fashion to a remote processing environment, comprising:
a control valve in communication with said supply meter for controlling said precursor liquid flow into a mixing manifold;
a vaporizer manifold in cooperation with a carrier gas supply and providing a carrier gas for contemporaneous delivery into said mixing manifold;
a vaporizing component including at least a heating element in communication with said mixing manifold and, in cooperation with a mixing material provided in said vaporizer body, causing a phase change of said liquid precursor into a vapor output; and
delivery of said vapor outlet along at least one high conductance run/vent valve located downstream from said vaporizing body for metering into a remote process chamber.

29. The device as described in claim 28, further comprising said control valve utilizing a mechanical deformation of a piezo crystal to provide motion to the valve seat.

30. The device as described in claim 28, said control valve utilizing electromagnetic force to provide motion to said valve seat.

31. The device as described in claim 28, said control valve utilizing pneumatic actuation to provide motion to said valve seat.

32. The device as described in claim 28, said control valve further comprising a combination of analog and digital circuitry.
